(19) United States
(12) Patent Application Publication
(10) Pub. No.: US 2012/0019290 A1
(43) Pub. Date: Jan. 26, 2012

(54) INPUT CIRCUIT

(75) Inventor: Tetsuya OGAWA, Ukyo-Ku (JP)

(73) Assignee: ROHM CO., LTD., Kyoto (JP)

(21) Appl. No.: 12/852,712

(22) Filed: Aug. 9, 2010

(30) Foreign Application Priority Data
Aug. 7, 2009 (JP) 2009-184860
Jul. 7, 2010 (JP) 2010-154815

(51) Int. Cl. H03L 7/00

(52) U.S. Cl. 327/143

(57) ABSTRACT

An input terminal receives an external input signal. An input transistor is arranged such that the control terminal thereof is connected to the input terminal, and configured to change its state according to the input signal. An initializing transistor is arranged between the input terminal and the ground terminal. When the power supply for the input terminal is turned on, the control circuit turns on the initializing transistor, following which the control circuit turns off the initializing transistor.

### BACKGROUND OF THE INVENTION

1. Field of the Invention

The present invention relates to an input circuit arranged in a semiconductor integrated circuit, and configured to receive an external signal.

2. Description of the Related Art

Typical semiconductor circuits configured to receive an external digital signal include, as an input stage, an input circuit (input buffer) having high input impedance. Examples of typical configurations of such input circuits include inverters, differential amplifiers, emitter follower circuits, source follower circuits, etc.

FIG. 1 is a circuit diagram which shows a configuration of a condenser microphone and a signal processing circuit 200 configured to receive an output signal of the condenser microphone. A condenser microphone 2 is represented by an equivalent circuit including a capacitor Cmic. The condenser microphone 2 is an electroacoustic transducer, and outputs an electrical signal S1 that corresponds to the sound input.

The signal processing circuit 200 includes an input circuit 210 and a signal processing unit 220. The input circuit 210 functions as a so-called buffer configured to receive, with high impedance, the electrical signal S1 from the condenser microphone 2. The input circuit 210 includes an input transistor M1 configured as a P-channel MOSFET (Metal Oxide Semiconductor Field Effect Transistor).

An electric current that corresponds to the electrical signal S1 passes through the input transistor M1. Alternatively, a voltage that corresponds to the electrical signal S1 occurs at the source of the input transistor M1. The input circuit 210 outputs, to the signal processing unit 220 provided as a downstream component, the current Is or the voltage Vs (which will be referred to as the “detection signal S2” hereafter) that corresponds to the electrical signal S1.

### RELATED ART DOCUMENTS

### Patent Documents

### [Patent Document 1]

Japanese Patent Application Laid Open No. H07-212148

The applicant has come to recognize that an arrangement employing the input circuit 210 shown in FIG. 1 has the following problems. That is to say, after the power supply for the signal processing circuit 200 is turned on, the power supply voltage Vdd rises, which raises the electric potential at the source of the input transistor M1. A parasitic capacitance Cgs occurs between the gate and the source of the input transistor M1. Accordingly, as the source potential Vs rises, the gate potential Vg rises. In order to receive the signal S1 from the condenser microphone 2, the gate potential Vg of the transistor M1 must be biased close to the ground electric potential. Accordingly, if the gate potential Vg rises immediately after the signal processing circuit 200 is started up, the signal processing circuit 200 cannot receive the signal S normally.

The condenser microphone 2 outputs a signal S1 with an audio band that ranges between tens of hertz and 20 kHz. Accordingly, the time constant determined by the capacitor Cmic (e.g., several picofarads) and the bias resistor Rbias (e.g., several gigaohms) is very long. As a result, if the gate voltage Vg temporarily rises, a very long period of time, on the order of several seconds, is required for the gate potential Vg to fall to close to the ground electric potential. This means that, immediately after the startup operation, the signal processing circuit 200 cannot receive the audio input for a long period of time.

Such a problem is not limited to such an input circuit configured to receive a signal from a condenser microphone, but can occur in various kinds of input circuits for various kinds of usages.

### SUMMARY OF THE INVENTION

The present invention has been made in order to solve such a problem. Accordingly, it is an exemplary purpose of the present invention to provide an input circuit which requires only a short period of time to become operable after the input circuit is started up.

An embodiment of the present invention relates to an input circuit. The input circuit comprises: an input terminal arranged so as to receive an external signal; an input transistor arranged such that a control terminal thereof is connected to the input terminal, and configured such that the state thereof changes according to the signal thus received; an initializing transistor arranged between the input terminal and a ground terminal; and a control circuit configured such that, when a power supply for the input circuit is turned on, the initializing transistor is turned on, following which the initializing transistor is turned off.

With such an embodiment, the initializing transistor is turned on immediately after the input circuit is started up. Thus, in this stage, the electric potential at the input terminal is fixed close to the ground electric potential. Subsequently, the initializing transistor is turned off after the power supply voltage is stabilized, which sets the input circuit to a state in which it can receive the input signal. That is to say, such an embodiment provides an input circuit which requires only a short period of time to become operable.

After the control circuit turns on the initializing transistor, the control circuit turns off the initializing transistor after a predetermined period of time elapses.

Also, the control circuit may comprise: a capacitor connected to the control terminal of the initializing transistor; a switch configured to set an electric potential at the capacitor to a level which turns on the initializing transistor when the power supply is turned on; and a discharge circuit configured to change the electric potential at the capacitor toward a level which turns off the initializing transistor.

Also, the discharge circuit may be configured as a constant current circuit which discharges a current (charge) from the capacitor.

Also, the discharge circuit may be configured as a resistor which discharges a current (charge) from the capacitor.

Also, a device including a capacitor arranged between the input terminal and the ground terminal may be connected to the input terminal. Also, a condenser microphone may be connected to the input terminal.

According to an embodiment, the input circuit may further comprise a bias resistor arranged between the input terminal and the ground terminal.

Also, an audio signal may be input to the input terminal.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a circuit diagram which shows a configuration of a condenser microphone and a signal processing circuit configured to receive the output signal of the condenser microphone;

FIG. 2A is a diagram which shows a configuration of a signal processing circuit including an input circuit according to an embodiment of the present invention, and FIG. 2B is a circuit diagram which shows a configuration of an input circuit according to a modification;

FIG. 3A is a time chart which shows the operation of the signal processing circuit shown in FIG. 2A, and FIG. 3B is a time chart which shows the operation of the signal processing circuit shown in FIG. 1;

FIG. 4 is a circuit diagram which shows a configuration of a signal processing circuit including an input circuit according to a modification; and

FIG. 5 is a circuit diagram which shows a configuration of a signal processing circuit including an input circuit according to a modification.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

In the present specification, the state represented by the phrase “the member A is connected to the member B” includes a state in which the member A is indirectly connected to the member B via another member that does not affect the electric connection therebetween, in addition to a state in which the member A is physically and directly connected to the member B.

Similarly, the state represented by the phrase “the member C is provided between the member A and the member B” includes a state in which the member A is indirectly connected to the member C, or the member B is indirectly connected to the member C via another member that does not affect the electric connection therebetween, in addition to a state in which the member A is directly connected to the member C, or the member B is directly connected to the member C.

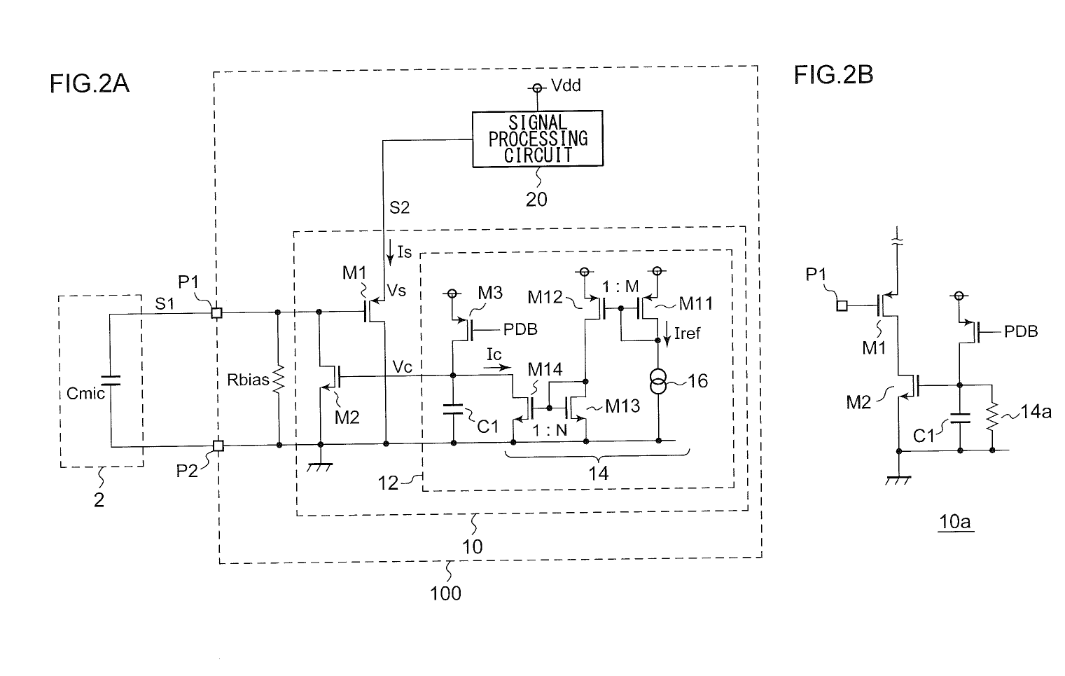

FIG. 2A is a diagram which shows a configuration of a signal processing circuit 100 including an input circuit 10 according to an embodiment of the present invention.

The signal processing circuit 100 includes the input circuit 10 and a signal processing unit 20. The signal processing circuit 100 receives an input signal S1 via an input terminal P1 from an external circuit. A ground terminal P2 is grounded. A bias resistor Rbias is arranged between the input terminal P1 and the ground terminal P2.

The input transistor M1 is configured as a P-channel MOSFET, and arranged such that the control terminal (gate) thereof is connected to the input terminal P1, and the input signal S1 is input to the control terminal thus connected. The state (the degree of the ON state) of the input transistor M1 changes according to the input signal S1. The input transistor M1 shown in FIG. 2A can be understood as a so-called source follower circuit. With such an arrangement, a detection voltage Vs that corresponds to the input signal S1 occurs at the source of the input transistor M1. Alternatively, a detection current Is that corresponds to the input signal S1 passes through the input transistor M1. The detection voltage Vs or the detection current Is (which will be referred to as the “detection signal S2” hereafter) is input to the signal processing unit 20 provided as a downstream component. In FIG. 2A, the input signal S1 is an audio signal output from the condenser microphone 2. The condenser microphone 2 is represented by an equivalent circuit including a capacitor Cmic connected in parallel.

An initializing transistor M2 is arranged between the input terminal P1 and the ground terminal P2. Specifically, the initializing transistor M2 is configured as an N-channel MOSFET, and arranged such that the source thereof is connected to the ground terminal P2, and the drain thereof is connected to the input terminal P1.

After the power supply for the input circuit 10 is turned on, the control circuit 12 turns on the initializing transistor M2, following which the control circuit 12 turns off the initializing transistor M2. Specifically, after a predetermined period of time T1 elapses after the control circuit 12 turns on the initializing transistor M2, the control circuit 12 turns off the initializing transistor M2. The predetermined period of time T1 is preferably set to be equal to or greater than a period of time required to stabilize the power supply voltage Vdd for the input circuit 10 (signal processing circuit 100).

The control circuit 12 includes a capacitor C1, a switch M3, and a discharge circuit 14. The capacitor C1 is arranged between the control terminal (gate) of the initializing transistor M2 and the ground terminal P2. When the power supply is turned on, the switch M3 sets the electric potential Vc at the capacitor C1 to a level which turns on the initializing transistor M2. For example, the switch M3 is configured as a P-channel MOSFET arranged such that the power supply voltage Vdd is applied to the source thereof, and the drain thereof is connected to the capacitor C1. A control signal PDB is applied to the control terminal (gate) of the switch M3. When the control signal PDB is low level, the switch M3 is on, and when the control signal PDB is high level, the switch M3 is off.

The discharge circuit 14 is configured to change the electric potential Vc at the capacitor C1 such that the initializing transistor M2 is turned off. The discharge circuit 14 shown in FIG. 2 is configured as a constant current circuit which discharges the current Ic from the capacitor C1. The discharge circuit 14 includes a constant current source 16 configured to generate a reference current Iref, and transistors M11 through M14 arranged such that they form current mirror circuits. By means of the current mirror circuits thus formed, the reference current Iref is multiplied by 1/(M×N), thereby generating a constant current Ic.

The above is the configuration of the signal processing circuit 100. Next, description will be made regarding the operation thereof.

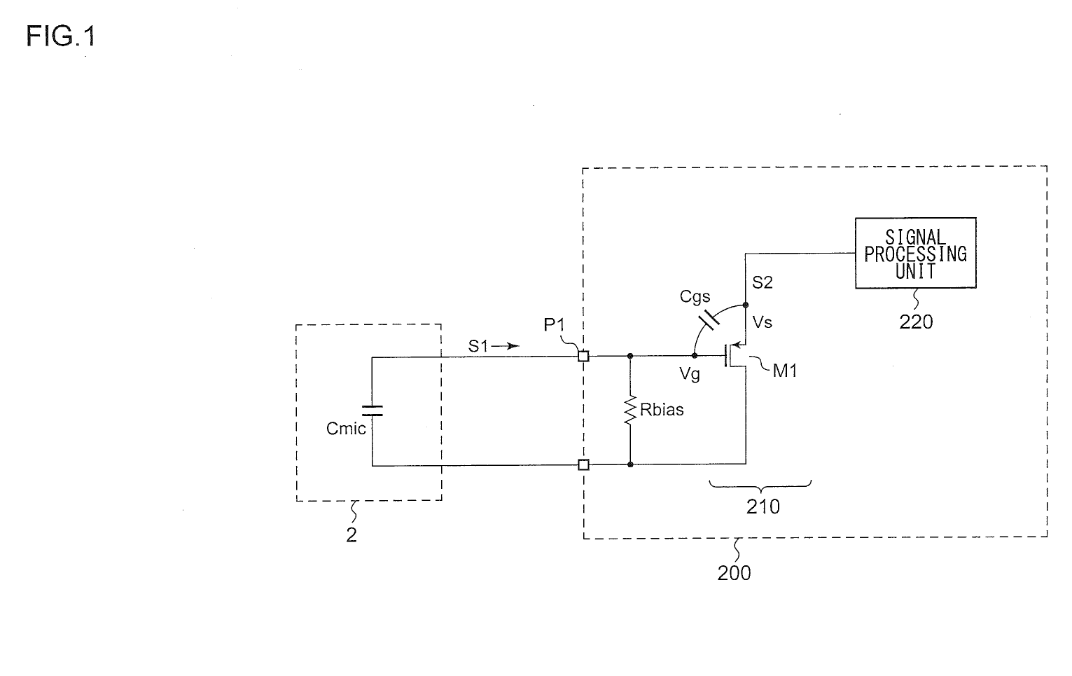

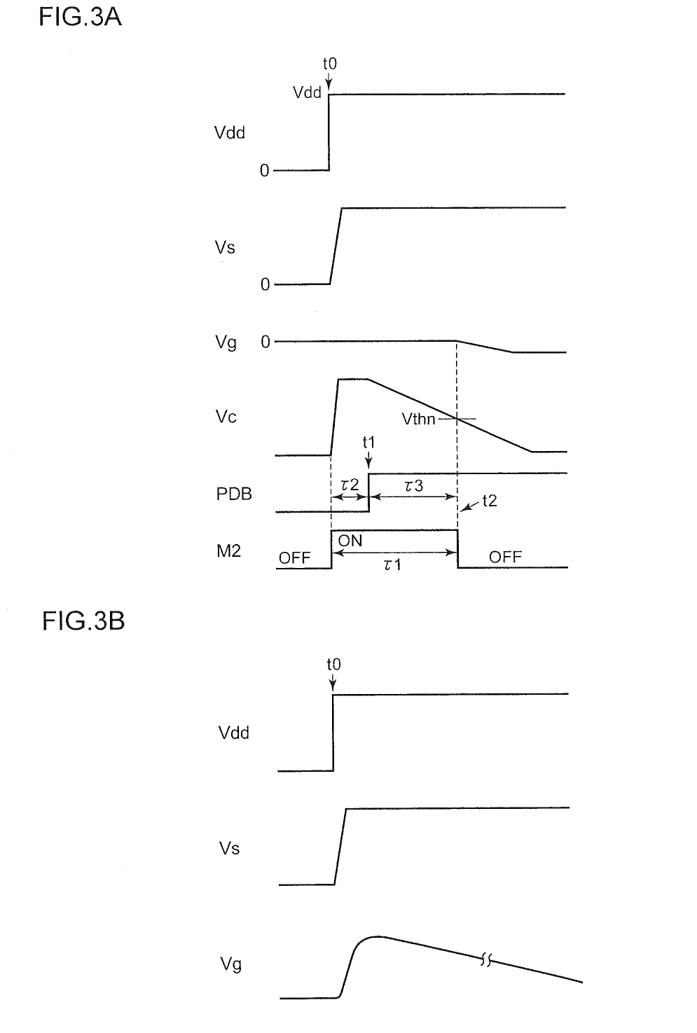

FIGS. 3A and 3B are time charts showing the operation of the signal processing circuit 100 shown in FIG. 2A and the operation of the signal processing circuit 200 shown in FIG. 1, respectively.

First, description will be made with reference to FIG. 3B so that the problems of the signal processing circuit 200 shown in FIG. 1 will be clearly understood. At the time point t0, the power supply is turned on, which raises the power supply voltage Vdd to a predetermined value. Subsequently, the source potential Vs of the input transistor M1 rises according to the increase in the power supply voltage Vdd. The gate of the input transistor M1 is coupled to the source via the gate-source capacitance Cgs. Accordingly, the gate potential Vg follows the source potential Vs.

With an arrangement shown in FIG. 1, only the bias resistor Rbias functions as a discharge path for the charge stored in the capacitance (Cmic and Cgs) connected to the input terminal P1. As described above, the resistance value of the bias resistor Rbias is very high (on the order of several gigaohms). Accordingly, the charge at the input terminal P1 is discharged very slowly. As a result, a very long period of time, on the order of several seconds for example, is required for the electric potential Vg at the input terminal P1 to fall to close to the ground potential such that the input circuit 210 is able to receive the input signal S1.

The above is the problem which the present applicant has come to recognize. Next, description will be made with reference to FIG. 3A regarding the operation of the signal processing circuit 100 shown in FIG. 2A configured to solve this problem.

At the time point t0, the power supply is turned on, which raises the power supply voltage Vdd. Immediately after the startup operation, the control signal PDB is set to low level, which turns on the switch M3. As a result, the electric potential Vc at the capacitor C1 is set to be nearly the same as the power supply voltage Vdd, thereby turning on the initializing transistor M2. When the initializing transistor M2 is on, the electric potential Vg at the input terminal P1 is fixed close to the ground electric potential (0 V). That is to say, unlike an arrangement shown in FIG. 3B, the electric potential Vg at the input terminal P1 does not rise.

After a predetermined period of τ2 elapses after the startup operation (at the time point t1), the control signal PDB is set to high level. In this stage, the switch M3 is turned off, which discharges the capacitor C1 via a constant current Ic. As the capacitor C1 is discharged, the electric potential Vc at the capacitor C1 drops over time. Subsequently, at the time point t2 when the electric potential Vc becomes lower than the gate threshold voltage Vthn of the initializing transistor M2, the initializing transistor M2 is turned off. After the initializing transistor M2 is turned off, the fixed electric potential at the input terminal P1 is canceled. In this state, the signal processing circuit 100 can receive the input signal S1. The period of time τ3, from when the capacitor C1 starts being discharged to when the initializing transistor M2 is turned off, is determined by the capacitance of the capacitor C1 and the constant current Ic.

The signal processing circuit 100 shown in FIG. 2A requires only a short period of time to be able to receive the input signal S1 after the power supply is turned on.

The above-described embodiment has been described for exemplary purposes only, and is by no means intended to be interpreted restrictively. Rather, it can be readily conceived by those skilled in this art that various modifications may be made by making various combinations of the aforementioned components or processes, which are also encompassed in the technical scope of the present invention. Description will be made below regarding such modifications.

FIG. 2B is a circuit diagram which shows a configuration of an input circuit 10a according to a modification. The input circuit 10a includes a resistor 14a which functions as a discharge circuit configured to discharge the capacitor C1. With such an arrangement, the period τ2, from when the capacitor C1 starts being discharged to when the initializing transistor M2 is turned off, is determined by a time constant defined by the capacitance of the capacitor C1 and the resistance of the resistor 14a.

Such a modification, too, can be set to a stable state, in which the input signal S1 can be received, in a short period of time.

According to the present invention, various modifications of the configuration of the input circuit 10 can be conceived. For example, the input transistor M1 shown in FIG. 2A or FIG. 2B may be replaced by an N-channel MOSFET. With such an arrangement, the input circuit 10 should be configured by inverting the configuration of the input circuit 10 shown in FIG. 2A or FIG. 2B.

The input circuit 10 is not restricted to such a source follower circuit. Also, the input circuit 10 may be configured as a differential amplifier (operational amplifier) or an inverter. In a case in which an N-channel MOSFET or a P-channel MOSFET is employed as an input stage for such a differential amplifier or an inverter, the same problem as in the circuit shown in FIG. 1 can occur. With the present invention, such a problem can be appropriately solved.

Also, the input signal S1 input to the signal processing circuit 100 is not restricted to an audio band signal (audio signal) received from the condenser microphone 2.

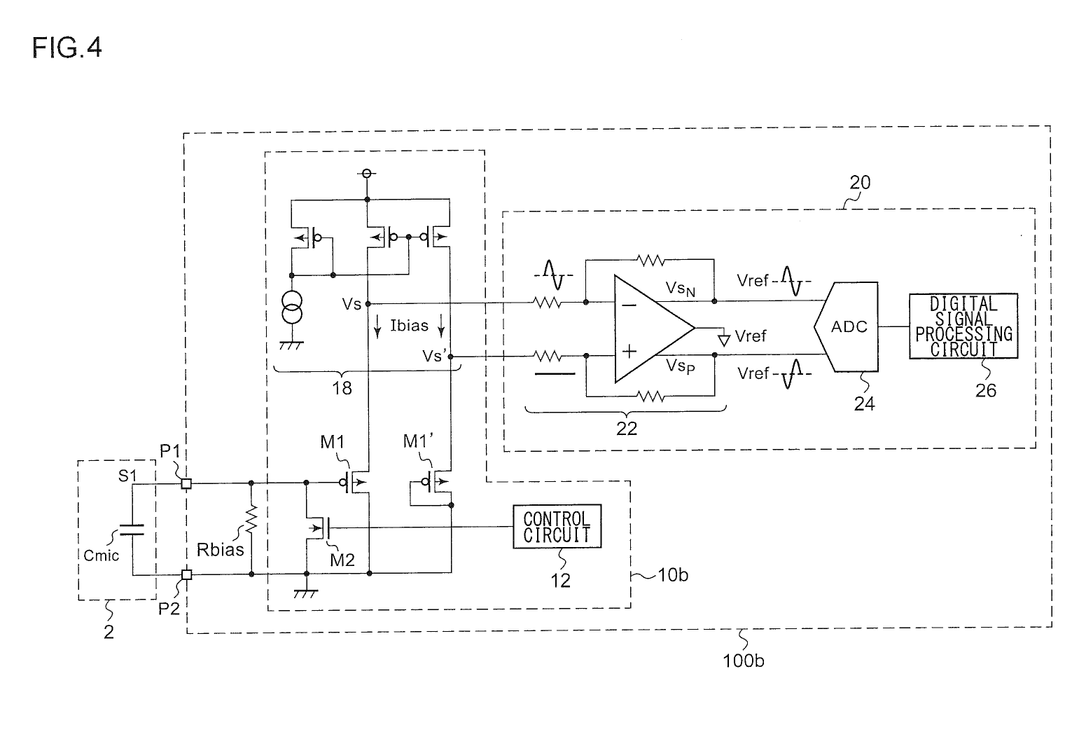

FIG. 4 is a circuit diagram which shows a configuration of a signal processing circuit 100b including an input circuit 10b according to a modification. The input circuit 10b includes an input transistor M1 and a second input transistor M1′ that is paired with the input transistor M1. The gate and the drain of the second input transistor M1′ are connected. A bias circuit 18 supplies a bias current Ibias to each of the input transistor M1 and the second transistor M1′. The voltage Vs′ having a predetermined level that corresponds to the bias current Ibias occurs at the source of the second input transistor M1′. Furthermore, at the source of the input transistor M1, a detection voltage Vs occurs, which changes according to the input signal S1, with the voltage Vs′ as the center point.

A differential amplifier 22 is arranged as a first stage of the signal processing unit 20. The differential amplifier 22 performs differential amplification of the voltage Vs and the voltage Vs′ received from the input circuit 10b, and converts the voltage Vs and the voltage Vs′ thus received into differential detection signals VsP and VsN, each of which change with the reference voltage Vref as the center point (common voltage).

An A/D converter 24 performs A/D conversion of the differential detection signals VsP and VsN received from the differential amplifier 22. A digital signal processing circuit 26 performs predetermined signal processing on the digital signal output from the A/D converter 24.

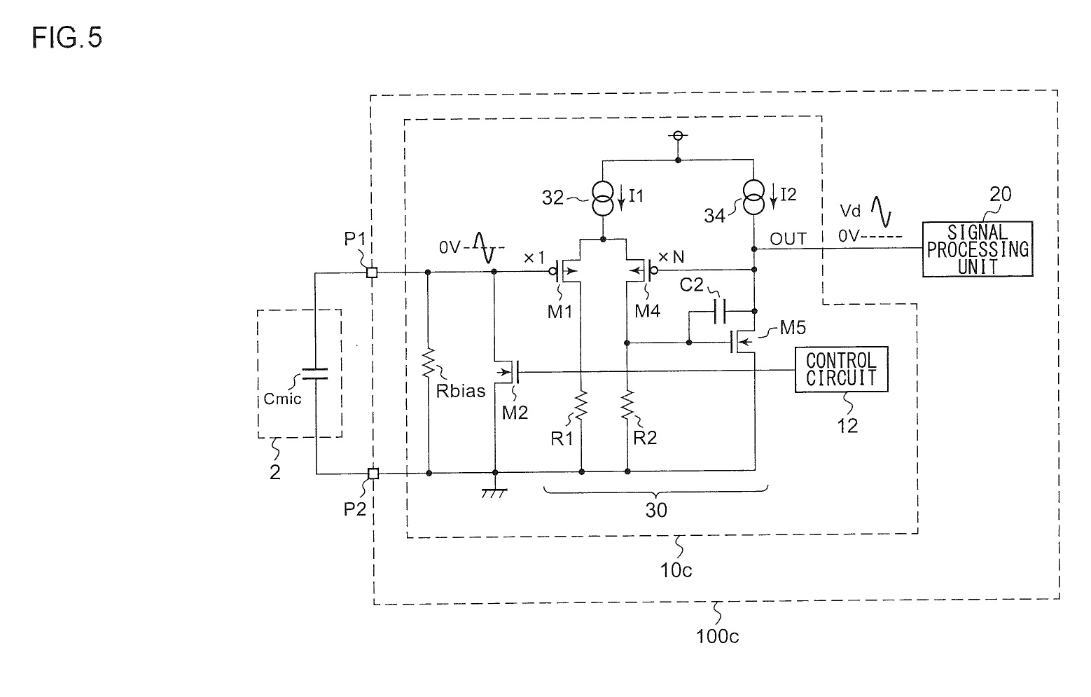

FIG. 5 is a circuit diagram which shows configuration of a signal processing circuit 100c including an input circuit 10c according to a modification. The input circuit 10c includes a differential amplifier 30. An input transistor M1 corresponds to one of the transistors that form an input differential pair. A resistor R1 which functions as a load is connected on the drain side of the input transistor M1. A second input transistor M4 corresponds to the other of the transistors that form the aforementioned input differential pair. A resistor R2 which functions as a load is arranged on the drain side of the second input transistor M4. The size of the second input transistor M4 is N times (N is a real number greater than 1) greater than the size of the transistor M1. An active load (current mirror circuit) may be provided instead of the resistors R1 and R2. A tail current source 32 supplies a tail current I1 to the differential pair M1 and M4.

A bias current source 34 generates a bias current I2. An output transistor M5 is arranged on a path for the bias current I2. The drain voltage of the transistor M4 is input to the gate of the output transistor M5, and a phase compensation capacitor C2 is arranged between the gate and the drain of the output transistor M5. The drain of the output transistor M5 functions as an output terminal OUT of the differential amplifier 30. The output terminal of the differential amplifier 30 is connected to the gate of the transistor M4.

The input circuit 10c is capable of converting the input signal S1, which changes with 0 V as the center point, into a positive detection voltage Vd, and of outputting the positive detection voltage Vd thus converted to the signal processing unit 20.

While the preferred embodiments of the present invention have been described using specific terms, such description is for illustrative purposes only, and it is to be understood that changes and variations may be made without departing from the spirit or scope of the appended claims.

What is claimed is:

1. An input circuit comprising:
an input terminal arranged so as to receive an external signal;
an input transistor arranged such that a control terminal thereof is connected to the input terminal, and configured such that the state thereof changes according to the signal thus received;
an initializing transistor arranged between the input terminal and a ground terminal; and
a control circuit configured such that, when a power supply for the input circuit is turned on, the initializing transistor is turned on, following which the initializing transistor is turned off.

2. An input circuit according to claim 1, wherein the control circuit comprises:
a capacitor connected to the control terminal of the initializing transistor;
a switch configured to set an electric potential at the capacitor to a level which turns on the initializing transistor when the power supply is turned on; and
a discharge circuit configured to change the amount of charge stored in the capacitor toward a level which turns off the initializing transistor.

3. An input circuit according to claim 2, wherein the discharge circuit is configured as a constant current circuit which discharges a current from the capacitor.

4. An input circuit according to claim 2, wherein the discharge circuit is configured as a resistor which discharges a current from the capacitor.

5. An input circuit according to claim 1, wherein a device including a capacitor arranged between the input terminal and the ground terminal is connected to the input terminal.

6. An input circuit according to claim 1, wherein a condenser microphone is connected to the input terminal.

7. An input circuit according to claim 5, further comprising a bias resistor arranged between the input terminal and the ground terminal.

8. An input circuit according to claim 6, further comprising a bias resistor arranged between the input terminal and the ground terminal.

9. An input circuit according to claim 1, wherein an audio signal is input to the input terminal.

10. An input circuit comprising:
an input terminal arranged so as to receive an external signal;
an input transistor arranged such that a control terminal thereof is connected to the input terminal, and configured such that the state thereof changes according to the signal thus received;
an initializing transistor arranged between the input terminal and a ground, terminal;
a control circuit configured such that, when a power supply for the input circuit is turned on, the initializing transistor is turned on, following which the initializing transistor is turned off;
a second input transistor configured as the same type of transistor as the aforementioned input transistor, and configured such that a control terminal and one terminal thereof are connected;
a bias circuit configured to supply a bias current to each of the aforementioned input transistor and the second input transistor;
a differential amplifier configured to perform differential amplification of a voltage that occurs at a connection node that connects the aforementioned input transistor and the bias circuit and a voltage that occurs at a connection node that connects the second input transistor and the bias circuit; and
an A/D converter configured to perform analog/digital conversion of an output signal of the differential amplifier.

11. An input circuit according to claim 10, wherein the control circuit comprises:
a capacitor connected to the control terminal of the initializing transistor;
a switch configured to set an electric potential at the capacitor to a level which turns on the initializing transistor when the power supply is turned on; and
a discharge circuit configured to change the amount of charge stored in the capacitor toward a level which turns off the initializing transistor.

12. An input circuit comprising:
an input terminal arranged so as to receive an external signal;
an input transistor arranged such that a control terminal thereof is connected to the input terminal, and configured such that the state thereof changes according to the signal thus received;
a second input transistor arranged such that one terminal thereof is connected to one terminal of the aforementioned input transistor;
load circuits respectively arranged on the other terminal side of the aforementioned input transistor and the other terminal side of the second input transistor;
a tail current source configured to supply a tail current to the aforementioned input transistor and the second input transistor;
an initializing transistor arranged between the aforementioned input terminal and the ground terminal;
a control circuit configured such that, when a power supply for the input circuit is turned on, the initializing transistor is turned on, following which the initializing transistor is turned off;
an output transistor arranged such that an electric potential at the aforementioned other terminal of the second input transistor is input to a control terminal thereof; and
a bias current source configured to supply a bias current to the output transistor.

13. An input circuit according to claim 12, wherein the control circuit comprises:
a capacitor connected to the control terminal of the initializing transistor;
a switch configured to set an electric potential at the capacitor to a level which turns on the initializing transistor when the power supply is turned on; and
a discharge circuit configured to change the amount of charge stored in the capacitor toward a level which turns off the initializing transistor.
